(19) United States
(12) Patent Application Publication
(10) Pub. No.: US 2011/0156740 A1
(43) Pub. Date: Jun. 30, 2011

(54) PROBE CARD

(75) Inventors: Gyu Man Hwang, Yongin (KR); Ji Hwan Shin, Yongin (KR); Yong Seok Choi, Suwon (KR)

(73) Assignee: SAMSUNG ELECTRO-MECHANICS CO., LTD.

(21) Appl. No.: 12/880,707

(22) Filed: Sep. 13, 2010

(30) Foreign Application Priority Data
Dec. 30, 2009 (KR) 10-2009-0134446

(51) Int. Cl. G01R 31/00; G01R 1/06

(52) U.S. Cl. 324/756.03

(57) ABSTRACT

There is provided a probe card. A probe card according to an aspect of the invention may include: a printed circuit board; a horizontal regulator passing through the printed circuit board and having an insertion portion having a horizontal regulation bolt and an insertion portion having a curved portion provided on an end portion of the horizontal regulation bolt; a probe substrate electrically connected to the printed circuit board; and a connection member mounted on the probe circuit, engaged with the horizontal regulation portion, and having an insertion recess therein so that the insertion portion is rotated within the insertion recess.

### CROSS-REFERENCE TO RELATED APPLICATIONS

This application claims the priority of Korean Patent Application No. 10-2009-0134446 filed on Dec. 30, 2009, in the Korean Intellectual Property Office, the disclosure of which is incorporated herein by reference.

### BACKGROUND OF THE INVENTION

1. Field of the Invention

The present invention relates to probe cards, and more particularly, to a probe card that facilitates horizontal regulation.

2. Description of the Related Art

In general, a semiconductor device is manufactured by a fabrication process in which circuit patterns and contact pads for inspection are formed on a wafer and an assembly process in which the wafer with the circuit patterns and the contact pads formed thereupon is divided into individual semiconductor chips.

Between the fabrication process and the assembly process, an inspection process is performed to check the electrical characteristics of the wafer by applying an electrical signal to the contact pads formed on the wafer.

The inspection process is performed in order to determine whether or not the wafer is defective, so as to remove a defective portion of the wafer during the assembly process.

During the inspection process, a tester applying an electrical signal to the wafer and a probe card serving as the interface between the wafer and the tester are widely used items of inspection equipment.

The probe card includes a printed circuit board (PCB) receiving the electrical signal applied from the tester, and a plurality of probes brought into contact with the contact pads formed on the wafer.

Recently, an increase in the demand for high integrated chips has lead to the realization of the high integration of both circuit patterns formed on a wafer through a fabrication process and contact pads connected with the circuit patterns on the wafer. That is, the distance between neighboring contact pads is extremely small, and the contact pads are extremely small-sized. Here, since the probes of the probe card used for the inspection process come into contact with the corresponding contact pads, the neighboring probes corresponding to the contact pads need to be separated from each other by an extremely small distance and have an extremely small size at the same time.

In order to inspect the contact pads having such fine pitches, the probes of the probe card are also formed to have fine pitches, for which a probe substrate, a so-called space transformer, is used between the PCB and the probes in order to compensate for the difference between the space between the terminals on the PCB and the distance between probes.

A plurality of probes are mounted on the bottom of a probe substrate. Most importantly, the ends of these probes are at the same height so that all of the probes may come into contact with all of the contact pads of the wafer. To this end, the horizontality of the probe substrate needs to be ensured.

### SUMMARY OF THE INVENTION

An aspect of the present invention provides a probe card that facilitates horizontal regulation.

According to an aspect of the present invention, there is provided a probe card including: a printed circuit board; a horizontal regulator passing through the printed circuit board and having an insertion portion having a horizontal regulation bolt and an insertion portion having a curved portion provided on an end portion of the horizontal regulation bolt; a probe substrate electrically connected to the printed circuit board; and a connection member mounted on the probe circuit, engaged with the horizontal regulation portion, and having an insertion recess therein so that the insertion portion is rotated within the insertion recess.

The curved portion may have a maximum diameter greater than a diameter of the horizontal regulation bolt.

The curved portion may have a maximum diameter greater than a diameter of the horizontal regulation bolt and may have a spherical shape, and the insertion recess of the connection member may receive the curved portion so that a depth of the insertion recess is greater than a maximum diameter of the curved portion.

The curved portion may have a maximum diameter greater than a diameter of the horizontal regulation bolt and may have a hemispherical shape, and the connection member may have an engagement portion so that the connection member covers the curved portion.

The horizontal regulation portion may further include a nut corresponding to the horizontal regulation bolt.

The probe card may further include a lateral jig supporting a side surface of the probe substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view schematically illustrating a probe card according to an exemplary embodiment of the present invention;

FIG. 2 is an enlarged sectional view schematically illustrating a region A of FIG. 1; and

FIG. 3 is an enlarged sectional view schematically illustrating a horizontal regulator of a probe card according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

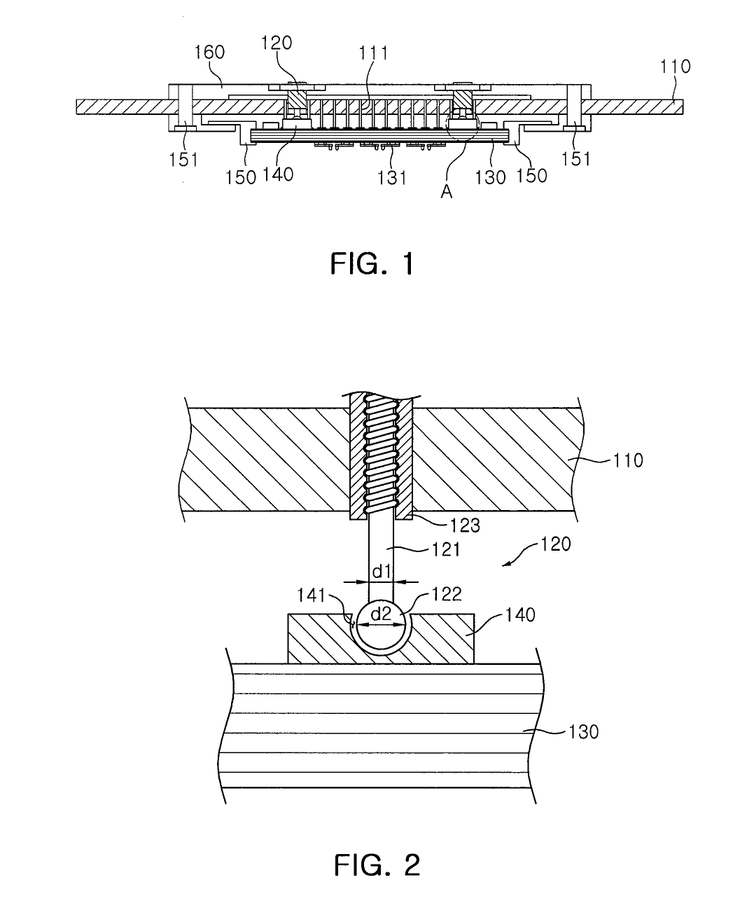

FIG. 1 is a cross-sectional view schematically illustrating a probe card according to an exemplary embodiment of the invention. FIG. 2 is an enlarged sectional view schematically illustrating a region A of FIG. 1.

Referring to FIG. 1, a probe card according to this embodiment includes a printed circuit board 110, horizontal regulators 120, a probe substrate 130, and connection members 140.

The printed circuit board 110 has probe circuit patterns (not shown) formed on atop surface thereof in order to perform an inspection process and holes formed in a bottom surface thereof to mount interposers 111 therein.

The printed circuit board 110 may be connected to a tester (not shown) for the inspection process.

Since the probe card is used to test high integrated wafers, the spacing between the neighboring probe circuit patterns, formed on the top surface of the printed circuit board 110, may be reduced.

The interposers 111 are interposed between the printed circuit board 110 and the probe substrate 130. One set of ends of the interposers 111 are connected to the probe circuit patterns of the printed circuit board 110, and the other set of ends are connected to the probe substrate 130.

The interposers 111 transmit electric signals, having passed through the printed circuit board 110, to the probe substrate 130 in order to perform the inspection process.

The interposers 111 are interface devices that electrically connect the printed circuit board 110 and the probe substrate 130 to each other. Further, the interposers 111 may have various shapes.

The probe substrate 130 may be a multilayer substrate formed of an insulating material, such as ceramic, glass or silicon. The interposers 111 are coupled to the top surface of the probe substrate 130 so that the probe substrate 130 is connected to the printed circuit board 110. A plurality of probes 131 coming into direct contact with an object to be tested (a wafer chip) are mounted on the bottom surface of the probe substrate 130.

The probe substrate 130 transmits the electric signals from the printed circuit board 110 to the plurality of probes 131.

The plurality of probes 131 come into direct contact with the object to be tested (the wafer chip) to transmit the electric signals thereto, and transmit electric signals from the object to be tested to the probe substrate.

The high integrated wafer has led to an increase in the size of the probe substrate and an increase in the number of probes. This means that a force to be applied to the probe substrate is increased so that the substrate may be curved inwardly. Thus, the horizontality of the probe card is controlled using a horizontal regulation device.

It is important for ends of the plurality of probes 131 to be at the same height so that all of the ends of the probes can come into contact with contact pads of the object to be tested. To this end, the horizontality of the probe substrate 130 needs to be ensured.

In this embodiment, the horizontality of the probe substrate 130 is controlled and maintained by the horizontal regulators 120. The horizontal regulators 120 are connected to a stiffener plate 160 and pass through the printed circuit board 110 so that the horizontal regulators 120 are connected to the probe substrate 130.

The horizontal regulators 120 each include a horizontal regulation bolt 121 and an insertion portion 122 having a curved portion formed on an end portion of the horizontal regulation bolt 121.

The connection members 140 are mounted on the probe substrate 130. The connection members 140 are engaged with the respective insertion portions 122 of the horizontal regulators 120. Insertion recesses 141 are formed in the respective connection members 140 so that the insertion portions 122 of the horizontal regulators 120 are rotated therein. The insertion portions 122 of the horizontal regulators 120 are inserted within the respective insertion recesses 141.

In order to perform the inspection process, the probe substrate 130 is assembled on the printed circuit board 110.

In order that the probe substrate 130 is assembled on the printed circuit board 110, the probe substrate 130 may be mounted on lateral jigs 150. The lateral jigs 150 are connected to the stiffener plate 160 and pass through the printed circuit board 110 so that the lateral jigs 150 support the sides of the probe substrate 130. The height of the lateral jigs 150 can be adjusted by lateral adjustment bolts 151.

In an assembling process, force is applied to the probe substrate 130 along the Z axis by the horizontal regulators 120 in order to obtain the horizontality of the probe substrate 130.

The horizontal regulators 120 may include nuts 123 respectively corresponding to the horizontal regulation bolts 121.

In order to obtain the horizontality of the probe substrate 130, the horizontal regulation bolts 121 are pulled so that force is applied to the probe substrate 130. Here, the insertion portions 122 of the horizontal regulators 120 are rotated within the insertion recesses 141 of the connection members 140 to thereby disperse the force being applied.

As shown in FIG. 2, the insertion portion 122 has a curved portion. A maximum diameter d2 of the curved portion may be greater than a diameter d1 of the horizontal regulation bolt 121. The curved portion may have a spherical shape. Here, the curved portion is received within the insertion recess 141 so that a depth of the insertion recess 141 is greater than the maximum diameter 2, thereby forming an engagement structure therebetween.

When a force is applied along the Z axis in order to adjust the horizontality of the probe substrate, if the force is applied in a single direction, an excessive amount of force is applied across the probe substrate.

However, in this embodiment, it is possible to pull the probe substrate in various directions by the rotation of the curved portion 122, thereby preventing unnecessary force from being applied to the probe substrate 130 and thus dispersing a force being applied thereto to thereby prevent damage to the probe substrate.

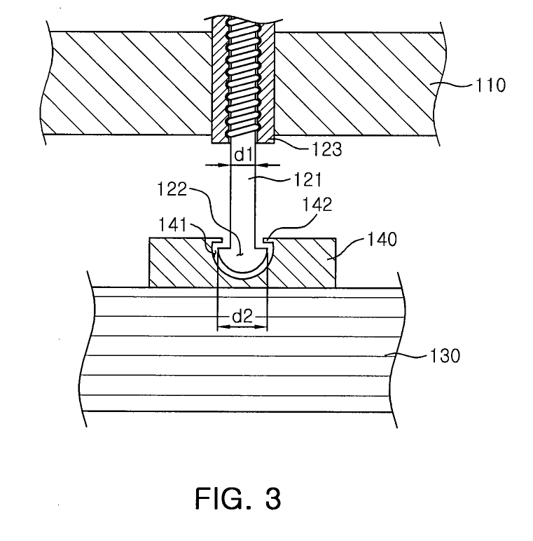

FIG. 3 is an enlarged sectional view schematically illustrating a horizontal regulator of a probe card according to another exemplary embodiment of the invention. A description will be made of components different from those of the above-described embodiment. A detailed description of the same components will be omitted.

This embodiment has the same configuration as the above-described embodiment except that an engagement structure between the horizontal regulators 120 and the connection members 140 is modified.

Referring to FIG. 3, a maximum diameter d2 of a curved portion may be greater than a diameter d1 of the horizontal regulation bolt 121, and the curved portion may have a hemispherical shape. Here, an engagement portion 142 may be formed on the connection member 140 so that the connection member 140 covers the curved portion.

As set forth above, according to exemplary embodiments of the invention, the horizontality of a probe substrate is controlled by a horizontal regulator. The horizontal regulator includes an insertion portion having a curved portion. The insertion portion is engaged with an insertion recess of a connection member mounted on the probe substrate. The curved portion is rotated when a force is applied to the probe substrate, thereby dispersing the force. Furthermore, it is possible to pull the probe substrate in various directions by the rotation of the curved portion, thereby preventing unnecessary force from being applied to the probe substrate.

While the present invention has been shown and described in connection with the exemplary embodiments, it will be apparent to those skilled in the art that modifications and variations can be made without departing from the spirit and scope of the invention as defined by the appended claims.

What is claimed is:

1. A probe card comprising:
a printed circuit board;
a horizontal regulator passing through the printed circuit board and having an insertion portion having a horizontal regulation bolt and an insertion portion having a curved portion provided on an end portion of the horizontal regulation bolt;
a probe substrate electrically connected to the printed circuit board; and
a connection member mounted on the probe circuit, engaged with the horizontal regulation portion, and having an insertion recess therein so that the insertion portion is rotated within the insertion recess.

2. The probe card of claim 1, wherein the curved portion has a maximum diameter greater than a diameter of the horizontal regulation bolt.

3. The probe card of claim 1, wherein the curved portion has a maximum diameter greater than a diameter of the horizontal regulation bolt and has a spherical shape, and the insertion recess of the connection member receives the curved portion so that a depth of the insertion recess is greater than a maximum diameter of the curved portion.

4. The probe card of claim 1, wherein the curved portion has a maximum diameter greater than a diameter of the horizontal regulation bolt and has a hemispherical shape, and the connection member comprises an engagement portion so that the connection member covers the curved portion.

5. The probe card of claim 1, wherein the horizontal regulation portion further comprises a nut corresponding to the horizontal regulation bolt.

6. The probe card of claim 1, further comprising a lateral jig supporting a side surface of the probe substrate.
